(19) United States
(12) Patent Application Publication
(10) Pub. No.: US 2025/0140706 A1
(43) Pub. Date: May 1, 2025

(54) BUS SYSTEM FOR A HIGH-POWER CONVERTER CIRCUIT

(71) Applicant: Eaton Intelligent Power Limited, Dublin 4 (IE)

(72) Inventor: Geraldo NOJIMA, Arden, NC (US)

(21) Appl. No.: 18/913,459

(22) Filed: Oct. 11, 2024

Related U.S. Application Data
(60) Provisional application No. 63/545,787, filed on Oct. 26, 2023.

(51) Int. Cl. H01L 23/538; H01L 23/367; H01L 23/64; H02M 3/00; H02M 3/158

(52) U.S. Cl. CPC H01L 23/5386; H01L 23/5385; H01L 23/64; H01L 23/3675; H02M 3/003; H02M 3/158

(57) ABSTRACT

A system and method for high voltage oscillation damping and capacitance controlling is provided. The system includes a high-voltage circuit including a first switching component and a second switching component connected in series and a layered bus system in electrical communication with the high-voltage circuit. The layered bus system includes alternating bus bar layers of an electrically insulative material and bus bar layers of a conductive material. The layers of the conductive material each comprise a first material and a second material, the second material having a higher resistivity than the first material. A geometry of the layers of the conductive material equalizes a capacitance across each of the first switching component and the second switching component.

### CROSS REFERENCE TO RELATED APPLICATION

This application claims the benefit of U.S. Provisional Application No. 63/545,787 filed Oct. 26, 2023.

### BACKGROUND

In power electronics, voltages are transformed by converter circuits, which are then coupled to other components through buses or other interconnecting or interfacing structures. Traditionally, silicon-based semiconductors have been used heavily in such converter circuits, however, wide-Bandgap and Ultrawide-Bandgap semiconductors are seeing increasing use in converter circuits due to their many superior physical traits, including operation in wider temperatures, voltages, and frequencies. In combination, this leads to faster, more efficient designs that are able to perform in more compact architectures.

High-power converter circuits can include switching modules comprising wide bandgap MOSFET devices that can operate at high voltages. Accordingly, high voltage as used herein can be at and above 600V, however, the high-power converter circuits discussed can operate in the voltage range of 0.6 kV to 60 kV. In addition, high power converter circuits include a bus system to interconnect the switching modules. As the bus system has inductive and capacitive parasitic components, during switching operation of the wide bandgap MOSFET devices, undesired oscillatory effects and electromagnetic interference (EMI) can be generated on the high-power converter circuit.

### BRIEF SUMMARY

A bus system for a high-power converter circuit is provided. The bus system is designed to provide oscillation damping to cope with the oscillatory effects generated by the switching operation of the wide bandgap MOSFET devices as well as to equalize the capacitance across each of two series connected switching modules comprising the wide bandgap MOSFET devices.

A system for high voltage oscillation damping and capacitance controlling includes a high-voltage circuit including a first switching component and a second switching component connected in series and a layered bus system in electrical communication with the high-voltage circuit. The layered bus system includes alternating bus bar layers of an electrically insulative material and bus bar layers of a conductive material. The layers of the conductive material each comprise a first material and a second material, the second material having a higher resistivity than the first material. A geometry of the layers of the conductive material equalizes a capacitance across each of the first switching component and the second switching component.

A method for high voltage oscillation damping and capacitance controlling in a high-power converter includes forming a layered bus system comprising alternating layers of electrically insulative material and layers of conductive material, electrically connecting the layered bus system with a high-voltage circuit, the high-voltage circuit including a first switching component and a second switching component in series, adding resistance to the layered bus system by forming the layers of conductive material of a first material and a second material, the second material having a higher resistivity than the first material, and controlling a capacitance in the high-power converter utilizing a geometry of the layers of the conductive material.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

To easily identify the discussion of any particular element or act, the most significant digit or digits in a reference number refer to the figure number in which that element is first introduced.

FIG. 1 illustrates a system for high voltage damping and capacitance control.

FIG. 2 illustrates a cross section through line A-A′ of switching module assemblies sandwiching a bus system interface as found in FIG. 1.

FIG. 3 illustrates a circuit diagram of a high-voltage circuit.

FIG. 4 illustrates a perspective view of a bus system.

FIG. 5 illustrates an exploded view of the bus system.

FIG. 6 illustrates a process flow describing a method for high voltage oscillation damping and capacitance controlling in a high-power converter.

### DETAILED DESCRIPTION

A bus system for a high-power converter circuit is provided. The bus system is designed to provide oscillation damping to cope with the oscillatory effects generated by the switching operation of the wide bandgap MOSFET devices as well as to equalize the capacitance across each of two series connected switching modules comprising the wide bandgap MOSFET devices.

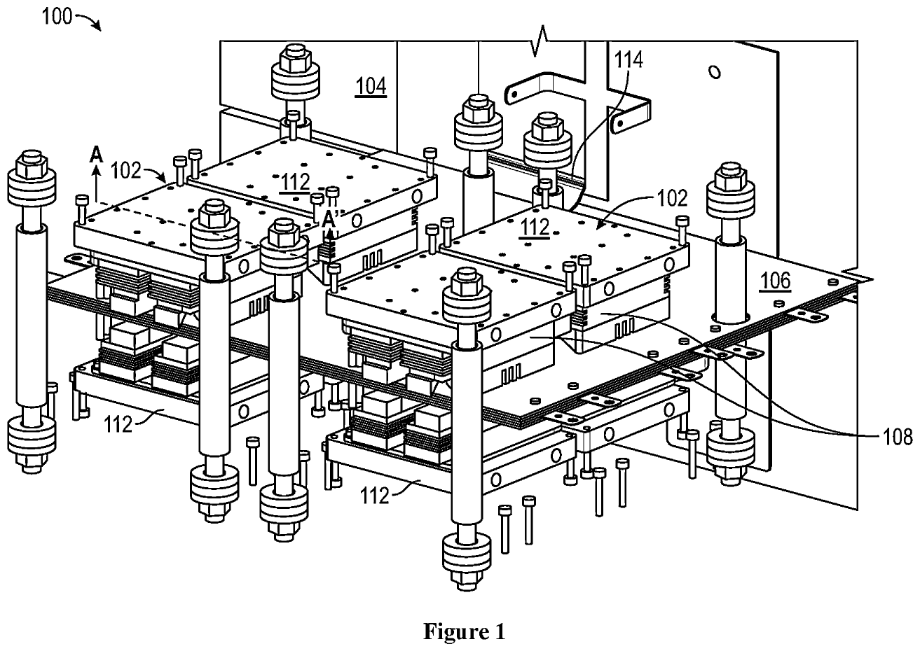

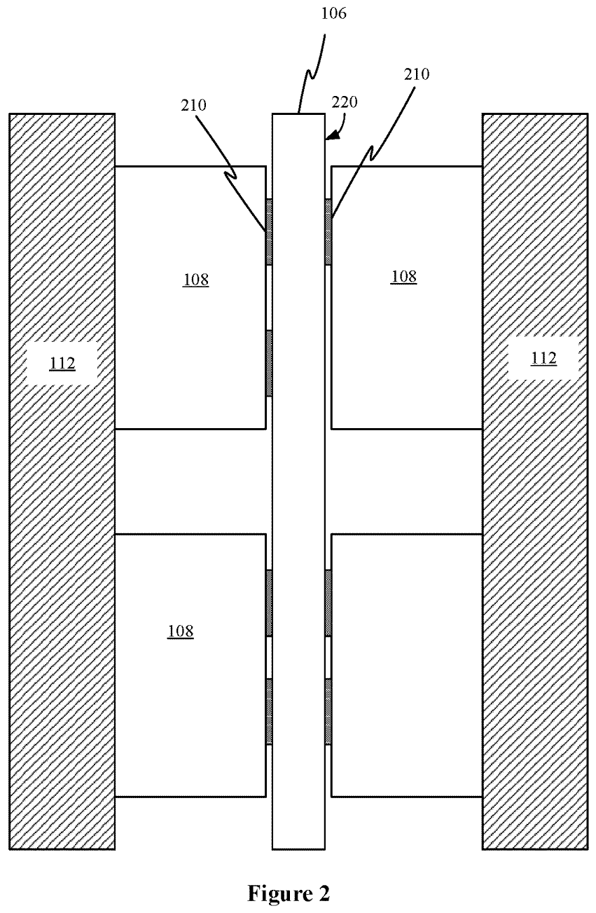

FIGS. 1 and 2 illustrate a system for high-voltage oscillation damping and capacitance control. FIG. 1 illustrates a perspective view of a high-power converter 100. Turning to FIG. 1, the high-power converter 100 includes a high-voltage circuit 102. In an embodiment, the high-voltage circuit 102 is a power electronics circuit. A plurality of modules 108 house the high-voltage circuit 102. Two of the modules 108 can be connected in series as shown in FIG. 1. FIG. 1 illustrates four sets of series connected modules 108. The modules 108, each including at least one switching component, can be connected in series to create a switching device of higher voltage capacity (up to 16 kV, for example) than single switching modules. The series connected switching components should operate synchronously as one switch. A DC power supply 104 is connected to the high voltage circuit 102 via an external bus 114 and provides DC power to the high-voltage circuit 102. The modules 108 are coupled to a bus system 106. The high-power converter 100 can also include a heat sink 112. The heat sink 112 may be formed of individual heat sinks for each module 108, as shown in FIG. 1, or a larger heat sink to which multiple modules are coupled.

FIG. 2 illustrates a cross section through line A-A′ of switching module assemblies sandwiching a bus system interface as found in FIG. 1. The switching modules 108 can be those found in FIG. 1 sandwiching bus system 106. FIG. 2 shows that bus system 106 can provide an interface between switching modules 108. Bus system 106 can be used to couple one or more switching components (e.g., housed in a module) with the external bus 114, such as that connecting high voltage circuit 102 with DC power supply 104, or another system. Each module 108 includes a lead line 210 that makes physical and electrical contact with a contact surface 220 of a structure in the form of conductive pads on the bus system 106.

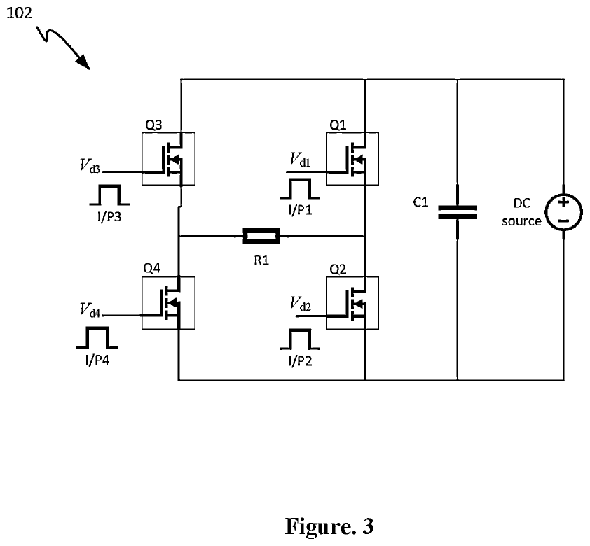

FIG. 3 illustrates a circuit diagram of a high voltage circuit. High voltage circuit 102 is representative of the high-voltage circuit that can be found within each module 108. High voltage circuit 102 includes a plurality of switching components, Q1, Q2, Q3, and Q4. A first switching component Q1 is connected in series to a second switching component Q2. A third switching component Q3 is connected in series to a fourth switching component Q4. The first switching component Q1 and the second switching component Q2 are positioned in parallel to the third switching component Q3 and the fourth switching component Q4. While the illustrated high voltage circuit 102 includes four MOSFET devices, each depicted MOSFET device Q1, Q2, Q3, and Q4 can represent two wide bandgap transistors in series.

A load, depicted by resistor R1, is positioned between the series connected MOSFET devices. The load can be a motor, a solenoid, and an actuator, for example. A DC link capacitor C1 is positioned in parallel to the series connected switching components 108. The DC link capacitor C1 provides a more stable voltage by limiting voltage fluctuations.

High voltage circuit 102 also includes a DC power supply 104 that provides a high voltage, such as up to 25 kV DC, to the high voltage circuit 102. High voltage circuit 102 is suitable to operate as a high voltage power converter. Switching components Q1, Q2, Q3, and Q4 can be wide bandgap MOSFET devices or, in some cases, ultra-wide bandgap MOSFET devices. Each switching component Q1, Q2, Q3, and Q4 has a corresponding gate driver V_{d1}, V_{d2}, V_{d3}, and V_{d4}. Each gate driver is a circuit used to produce a high current drive input for the gate of the at least one wide bandgap transistor on the switching module 108. Through the control signals of a controller (not shown), the gate driver switches on and off the corresponding wide bandgap transistor(s) in the high voltage circuit 102.

In general, switching components in high-voltage circuitry can be connected by a bus system. Each connection includes parasitic components such as inductances and capacitances. Every time the switching components switch on and off, because of the parasitic components, a high frequency oscillatory response is induced in the high voltage circuit 102. Adding resistance to the high voltage circuit 102 can dampen the oscillations, however, because it is desired that the high voltage circuit 102 is efficient, no resistors are used in high voltage circuit 102. Due to the oscillations, there can be a significant rise in voltage (voltage greater than that of the DC power supply 104) across the switching components of the high voltage circuit 102. Traditionally, snubbers comprising a high voltage discrete resistor and capacitor are used to limit the voltage. However, the snubbers have poor effectiveness, add significant cost, and increase power loss.

The voltage balance during the turn-on and turn-off transitions between switching modules 108 in series depends on the equality of the total capacitance across each of the modules. When the capacitances are not equal, transient voltage sharing under transient conditions cannot be achieved. A capacitance can be added in parallel to each of the switching modules to equalize and synchronize the capacitance across series connected switching modules. However, in order to compensate for the induced inductances and capacitances generated in a high voltage circuit, an unreasonably large capacitance value would have to be added to accommodate a high voltage circuit.

In order to mitigate the problems discussed above, a bus system is proposed.

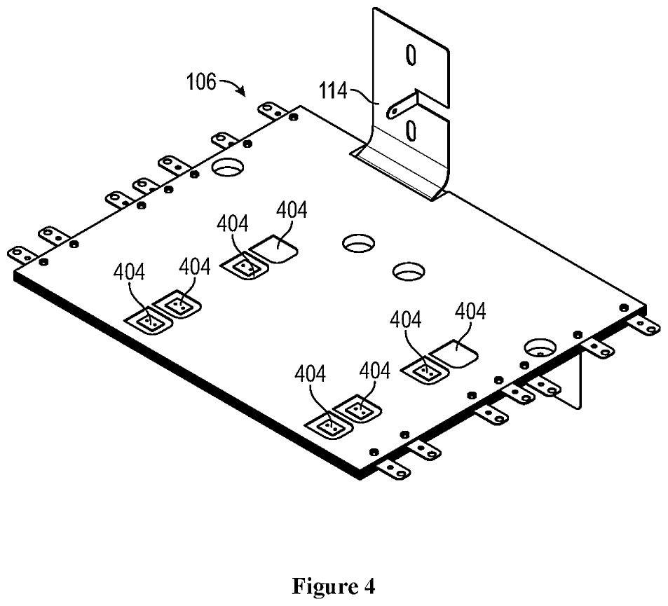

FIG. 4 illustrates a perspective view of a bus system. Bus system 106 can be coupled to the DC power supply 104, or another system, by external bus 114. Bus system 106 includes sets of two conductive pads 404 for electrical connections to each of the switching modules 108.

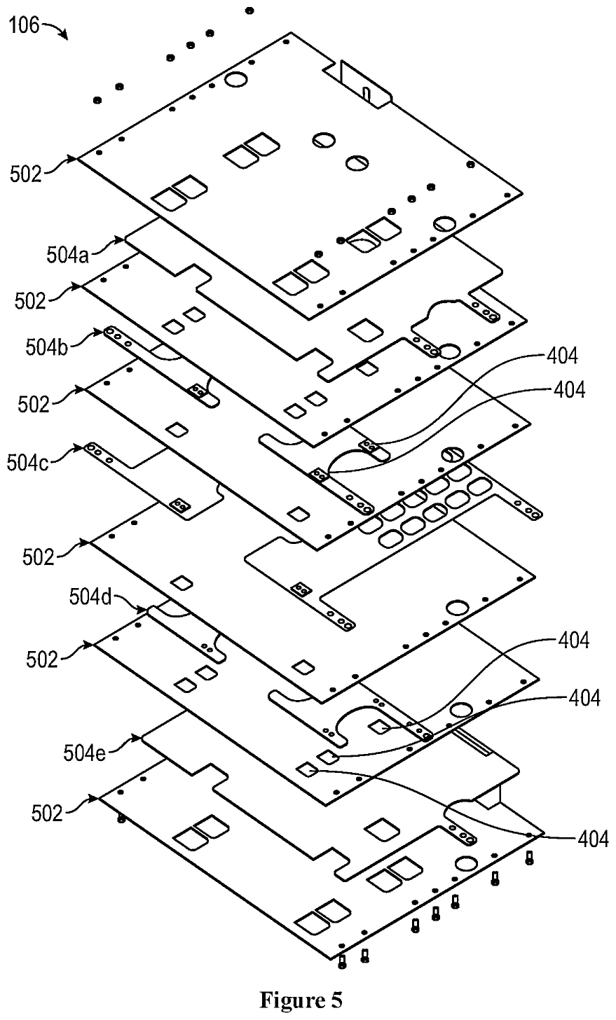

FIG. 5 illustrates an exploded view of the bus system. Bus system 106 includes a plurality of layers. The plurality of layers includes alternating layers of electrically insulating material 502 and conductive material 504 as seen in FIG. 5.

In some cases, each layer of the plurality of layers comprises a plate. The plates making up the bus system 106 are wide plates, in some cases, 12 in wide and ¼ in thick, that can carry large current flows, e.g., 500-1000 amps, while suppressing the formation of a magnetic field. Each of conductive plates includes conductive pads 404 that connect to the MOSFET devices in the respective switching module 108. Conductive plates 504a and 504e respectively connect to the positive and negative terminals of the MOSFET devices. In FIG. 5, connective plate 504c is the output of the high-power converter 100.

In order to add resistivity to the high voltage circuit 102, the conductive plates 504a, 504b, 504c, 504d, 504e can be formed from a first material and a second material, the second material having a higher resistivity than the first material. In some cases, the conductive plates 504a, 504b, 504c, 504d, 504e comprise the first material interspersed with one or more segments of the second material. In other cases, the conductive plates 504a, 504b, 504c, 504d, 504e each comprise an alloy, the alloy including a mixture of the first material and the second material the first material. The percentages of each of the first material and the second material in the mixture will depend on the design of the converter. The alloy can have a resistivity that is more than the first material. Each conductive plate 504a, 504b, 504c, 504d, 504e formed of the alloy can be formed utilizing 3D printing. In an embodiment, the first material can be aluminum or copper and the second material can be stainless steel. By forming the conductive layers 504a, 504b, 504c, 504d, 504e of a resistive material, resistance can be distributed throughout the layered bus system.

In some cases, the geometry of the layers of the conductive material can be utilized to control capacitance in the high-power converter 100. For example, in order to control parasitic capacitance between the conductive plate 504c, e.g., the output of the high-power converter 100, as shown in FIG. 5, and conductive plates 504b and 504d, a plurality of holes 506 can be formed in conductive plate 504c. The capacitance can be reduced in this example by removing material of the plate 504c as the capacitance depends upon area of the conductive material. In a further example, in order to control the capacitance across each of the switching modules 108, conductive material can be added to the conductive plates 504. For example, conductive material has been added to conductive plates 504b and 504d corresponding to the placement of the conductive pads 404. Thus, the geometry of the conductive plates 504a, 504b, 504c, 504d, 504e can impose a capacitance to equalize the capacitance across switching modules 108 connected in series.

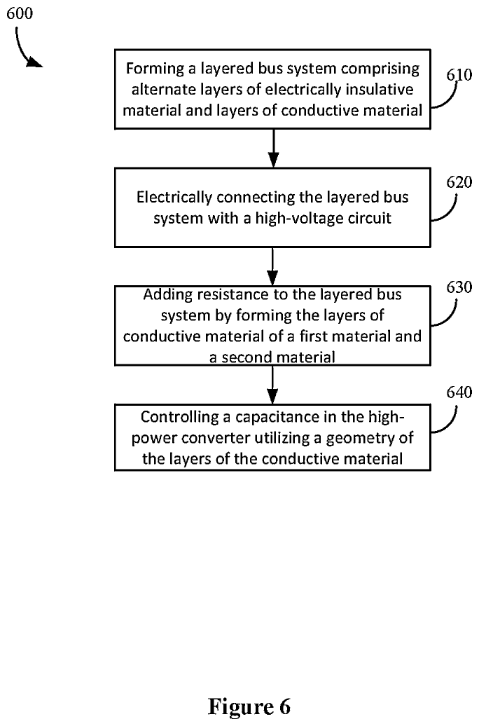

FIG. 6 illustrates a process flow describing a method for high voltage oscillation damping and capacitance controlling in a high-power converter. Referring to FIG. 6, the method 600 includes forming (610) a layered bus system comprising alternating layers of electrically insulative material and layers of conductive material. The method 600 includes electrically connecting (620), the layered bus system with a high-voltage circuit. The high voltage includes a first switching component and a second switching component in series. Resistance is added (630) to the layered bus system by forming the layers of conductive material of a first material and a second material. The second material has a higher resistivity than the first material. Capacitance is controlled (640) in the high-power converter utilizing a geometry of the layers of the conductive material.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A system for high voltage oscillation damping and capacitance controlling, the system comprising:
a high-voltage circuit including a first switching component and a second switching component connected in series; and
a layered bus system electrically connected to the high-voltage circuit, the layered bus system comprising alternating bus bar layers of an electrically insulative material and bus bar layers of a conductive material,
wherein the layers of the conductive material each comprise a first material and a second material, the second material having a higher resistivity than the first material, and
wherein a geometry of the layers of the conductive material equalizes a capacitance across each of the first switching component and the second switching component.

2. The system of claim 1, wherein the high-voltage circuit is a power electronics circuit.

3. The system of claim 1, wherein the first switching component and the second switching component are wide bandgap transistors.

4. The system of claim 1, wherein each of the layers of conductive material and each of the layers of the electrically insulative material comprises a plate.

5. The system of claim 4, wherein each layer of the layers of the conductive material comprise the first material interspersed with one or more segments of the second material.

6. The system of claim 4, wherein the layers of the conductive material comprise an alloy, the alloy including a mixture of the first material and the second material.

7. The system of claim 1, wherein the first material is aluminum or copper.

8. The system of claim 1, wherein the second material is stainless steel.

9. A method for high voltage oscillation damping and capacitance controlling in a high-power converter, comprising:
forming a layered bus system comprising alternating layers of electrically insulative material and layers of conductive material;
electrically connecting the layered bus system with a high-voltage circuit, the high-voltage circuit including a first switching component and a second switching component in series;
adding resistance to the layered bus system by forming the layers of conductive material of a first material and a second material, the second material having a higher resistivity than the first material; and
controlling a capacitance in the high-power converter utilizing a geometry of the layers of the conductive material.

10. The method of claim 9, wherein the capacitance is controlled utilizing the geometry of the layers of the conductive material to equalize the capacitance across the first switching component and the second switching component.

11. The method of claim 9, wherein the capacitance is controlled utilizing the geometry of the layers of the conductive material to reduce the capacitance between layers of the conductive material.

12. The method of claim 9, wherein each of the layers of conductive material and each of the layers of the electrically insulative material comprises a plate.

13. The method of claim 12, wherein forming the layers of conductive material includes forming each conductive plate of the first material interspersed with one or more segments of the second material.

14. The method of claim 12, wherein forming the layers of conductive material includes 3D printing each conductive plate with a mixture of the first material and the second material so that conductive plate comprises an alloy having a higher resistivity than the first material.

15. The method of claim 9, wherein the first material is aluminum or copper.

16. The method of claim 9, wherein the second material is stainless steel.
